(19) United States
(12) Patent Application Publication
(10) Pub. No.: US 2005/0136653 A1
(43) Pub. Date: Jun. 23, 2005

(54) Non-adhesive semiconductor wafer holder and assembly

(76) Inventors: Jose Govea Ramirez, Tucson, AZ (US); Robert O. Graham, Richardson, TX (US)

Correspondence Address: Dan Swayze;Texas Instruments Incorporated, M/S 3999, P. O. Box 655474, Dallas, TX, 75265, US

(21) Appl. No.: 10/744,469

(22) Filed: Dec. 22, 2003

(51) Int. Cl. H01L 21/4763

(52) U.S. Cl. 438/646

(57) ABSTRACT

A semiconductor wafer holder (12) and process eliminating the need for wafer mounting using sticky tape, UV exposure, and manual de-taping from sticky tape during processing and inspection. The present invention comprises a semiconductor holder having an opening (14) securely receiving a semiconductor wafer (16) about its edges in an interference fit. The holder securely holds the wafer in place during handling, and without the need for using sticky tape to hold the wafer backside to a wafer tray (30). The wafer holder is utilized as an insert that is concentric to the wafer tray, which tray includes a perforated film (32) having vacuum openings (34). Advantageously, sticky tape is only interposed between the wafer holder (12) and a perimiter of the wafer holder (30), which sticky tape is later removed using UV exposure.

### FIELD OF THE INVENTION

The present invention is generally related to semiconductor wafer processing handling systems, and more particularly to devices and methods used for processing semiconductor wafers in a film frame assembly.

### BACKGROUND OF THE INVENTION

Conventional semiconductor wafer handling systems typically utilize semiconductor trays to carry a semiconductor wafer during processing and during inspection of the wafer after processing. Conventionally, a sticky tape is utilized to secure a bottom surface of the semiconductor wafer to the wafer tray during this processing and inspection process. After wafer processing and inspection, the sticky film is exposed to a UV light to remove the sticky tape and adhesive. The semiconductor wafer is thereafter handled using a vacuum coupled to the wafer bottom surface.

Semiconductor processing and inspection is an expensive process, and the throughput time for the processing and inspection attributable to handling reduces the number of wafers that can be processed in a given amount of time. Most semiconductor processing fabs run 24 hours 7 days a week. Therefore, reducing the handling time between processing and inspection is an important goal to maximize output of the fab.

### SUMMARY OF THE INVENTION

The present invention achieves technical advantages as a semiconductor wafer holder and process which eliminates the wafer mounting process using sticky tape during processing and inspection. The wafer holder resiliently secures the wafer about its edge, eliminating the need for sticky tape.

The wafer holder is adapted to securely receive the semiconductor wafer about its edge, without the use of sticky tape. The insert receives the edges of the semiconductor wafer in a friction fit, and is preferably comprised of a resilient material, such as silicon sponge. The wafer holder has an opening shaped and sized to the semiconductor wafer, and which opening is concentric within the wafer holder. This wafer holder secures the wafer in place during handling and inspection. The wafer holder is assembled to a wafer frame having a perforated film, and only the wafer holder is secured thereto using sticky tape. The sticky tape is later exposed to UV light to remove the sticky tape from the holder. This wafer film is perforated to allow vacuum transmission to the wafer backside.

Handling time of a semiconductor wafer using the present invention cuts about 10 minutes off the process time per wafer when processed individually, and cuts about 5 minutes per wafer when processing more than one wafer. This wafer holder and process eliminates the need for more expensive handling systems which is a significant cost advantage over conventional processing. The present invention eliminates the risk of highly potential damage at mounting, as well as reducing the ESD factor. The present invention also reduces potential handling damages when detaching a wafer from the sticky tape, and eases the placing and removing of the wafers with minimal human handling.

### BRIEF DESCRIPTION OF THE DRAWINGS

FIG. 1 is a layout diagram of the wafer holder of the present invention received in a standard frame;

FIG. 2 is an exploded view of the wafer, wafer holder and standard frame having a perforated film; and

FIG. 3 is a flow diagram for processing and handling a wafer using the wafer holder of the present invention.

### DETAILED DESCRIPTION OF THE PREFERRED EMBODIMENT

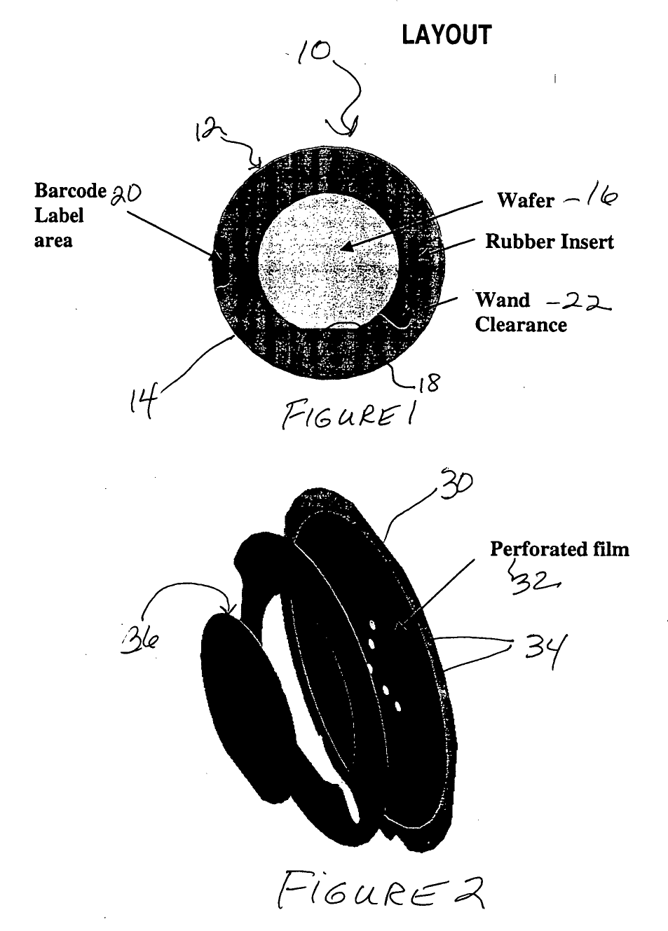

Referring now to FIG. 1, there is generally shown at 10 a top view of a layout of the present invention seen to comprise a semiconductor wafer holder 12. Wafer holder 12 has a concentric opening 14 having a size and profile adapted to securely engage the edge of a semiconductor wafer 16. The wafer holder 12 is seen to be generally circular, wherein opening 14 has a profile including a flat edge 18 that conforms to the flat edge of the semiconductor wafer 16. The wafer holder 12 is preferably comprised of a resilient material such as a rubber insert and comprised of a silicon foam material, to provide a resilient edge defining opening 14. Of course, other resilient materials are suitable which are resilient to securingly engage the perimeter of the semiconductor wafer 14 in an interference fit, and without damage thereto. The wafer holder 12 may also include a bar code label area 20, and a wand clearance 22.

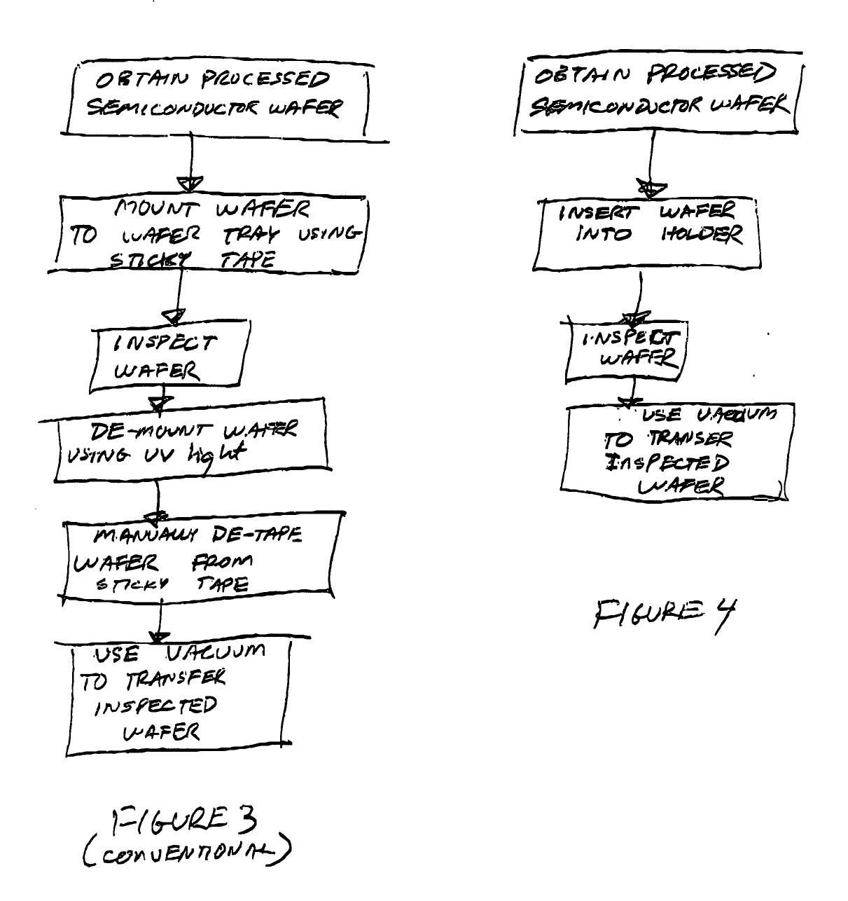

Referring now to FIG. 2, there is shown an exploded view of the semiconductor holder 12 adapted to be received upon a standard wafer frame 30 comprised of a wafer tray. Tray 30 is seen to have a recess for securely receiving the semiconductor holder 12 and has a perforated film 32 extending thereacross with perforations 34 permitting a vacuum to apply a vacuum pressure to the backside of the semiconductor wafer 16. The outer perimeter of the perforated film 32 includes sticky tape adapted to secure only to the bottom surface of the holder 12, such that the wafer backside 36 is secured in place with respect to the tray 30 by the secured wafer holder 12, and not the sticky tape. The semiconductor holder 12 is concentric to the inner frame diameter of holder 30, as shown. During processing, care is taken to make sure that the tray wafer cavity 30 and base is thoroughly cleaned from particles before using. Proper handling of tray 30 is that it be maintained completely covered when not in use, and is periodically inspected for material integrity.

The present invention achieves technical advantages in that the semiconductor wafer 16 is secured with respect to the wafer tray 30 about it periphery edge by the wafer holder 12, and without the use of any sticky tape. Advantageously, the handling and processing of the semiconductor wafer according to the present invention eliminates three processes, wafer mounting, UV exposure, and manual de-taping of the wafer from sticky tape. Processing time is reduced by approximately 10 minutes per wafer when processed individually, and is reduced by about 5 minutes per wafer when processing more than one wafer. In addition, the present invention eliminates the need for expensive handling systems, and the need for using sticky tape to hold the wafer 16 in place during processing and inspection. In addition, the present invention eliminates the risk of highly potential damage at mounting and de-mounting, and also reduces the ESD factor. Specifically, the present invention eliminates potential handling damages which may occur when removing a wafer from the sticky tape, and eases placing and removing the wafers with minimal human handling. The ease of manufacturing provides a lower processing cost, and a higher processing throughput.

Referring now to FIG. 3 there is shown a conventional process, and FIG. 4 illustrates a process according to the present invention, the side-by-side comparison showing the eliminated steps of wafer mounting, UV exposure, and manual de-taping of the wafer from sticky tape.

Table 1 below illustrates repeatability data for a 150 mm whole wafer tray insert, illustrating that the wafer holder used during processing complies with test perimeters, such as when the standard deviation for each defect measured is under 10.4 um.

TABLE ONE
150 mm WHOLE WAFER TRAY INSERT REPEATABILITY DATA

| | | | | | | | | | | | | | | Pass/ |
|---|---|---|---|---|---|---|---|---|---|---|---|---|---|---|
| Die | Defect | Run I | Run 2 | Run 3 | Run 4 | Run 5 | Run 6 | Run 7 | Run 8 | Run 9 | Run 10 | Average | STDEV | Fail |
| 29,44 | 1 | 319 | 313.76 | 313.76 | 313.76 | 313.76 | 313.76 | 313.76 | 313.76 | 313.76 | 313.76 | 314.284 | 1.65703 | Pass |
| 30,46 | 2 | 26.59 | 26.59 | 26.59 | 26.59 | 26.59 | 26.59 | 26.59 | 26.59 | 26.59 | 26.59 | 26.59 | 3.2E-07 | Pass |
| 30,46 | 3 | 34.57 | 34.57 | 31.91 | 34-57 | 34.57 | 34.57 | 34.57 | 34.57 | 34.57 | 34.57 | 34.304 | 0.84117 | Pass |
| 30,46 | 4 | 21.27 | 21.27 | 21.27 | 21.27 | 21.27 | 21.27 | 21.27 | 21.27 | 21.27 | 21.27 | 21.27 | 0 | Pass |
| 30,47 | 5 | 10.64 | 10.64 | 10.64 | 10.64 | 10.64 | 10.64 | 10.64 | 10.64 | 10.64 | 10.64 | 10.64 | 0 | Pass |
| 30,50 | 6 | 63.82 | 63.82 | 63.82 | 63.82 | 63.82 | 63.82 | 63.82 | 61.16 | 63.82 | 63.82 | 63.554 | 0.84117 | Pass |
| 30,50 | 7 | 23.93 | 23.93 | 23.93 | 23.93 | 23.93 | 23.93 | 23.93 | 23.93 | 23.93 | 23.93 | 23.93 | 0 | Pass |
| 31,45 | 8 | 31.91 | 31.91 | 31.91 | 29.25 | 29.25 | 29.25 | 29.25 | 31.91 | 29.25 | 29.25 | 30.314 | 1.37362 | Pass |
| 31,46 | 9 | 15.96 | 15.96 | 15.96 | 15.96 | 15.96 | 15.96 | 15.96 | 15.96 | 15.96 | 15.96 | 15.96 | 0 | Pass |
| 31,48 | 10 | 15.95 | 15.95 | 15.95 | 15.95 | 15.95 | 15.95 | 15.95 | 15.95 | 15.95 | 15.95 | 15.95 | 0 | Pass |
| 32,43 | 11 | 21.27 | 21.27 | 21.27 | 21.27 | 21.27 | 21.27 | 21.27 | 21.27 | 21.27 | 21.27 | 21.27 | 0 | Pass |
| 32,45 | 12 | 34.57 | 34.57 | 34.57 | 34.57 | 34.57 | 34.57 | 34.57 | 34.57 | 34.57 | 34.57 | 34.57 | 4.5E-07 | Pass |
| 32,45 | 13 | 63.82 | 63.82 | 63.82 | 63.82 | 63.82 | 63.82 | 63.82 | 63.82 | 63.82 | 63.82 | 63.82 | 0 | Pass |
| 32,45 | 14 | 15.95 | 15.95 | 15.95 | 15.95 | 15.95 | 15.95 | 15-95 | 15-95 | 15.95 | 15.95 | 15.95 | 0 | Pass |
| 32,46 | 15 | 21.27 | 21.27 | 21.27 | 21.27 | 21.27 | 21.27 | 21.27 | 21.27 | 21.27 | 21.27 | 21.27 | 0 | Pass |
| 33,43 | 16 | 21.27 | 21.27 | 21.27 | 21.27 | 21.27 | 21.27 | 21.27 | 21.27 | 21.27 | 21.27 | 21.27 | 0 | Pass |
| 33,44 | 17 | 18.61 | 18.61 | 18.61 | 15.95 | 15.95 | 15.95 | 15.95 | 15.95 | 18.61 | 18.61 | 17.28 | 1.40194 | Pass |
| 33,45 | 18 | 47.86 | 47.86 | 47.86 | 47.86 | 47.86 | 47.86 | 47.86 | 47.86 | 47.86 | 47.86 | 47.86 | 0 | Pass |
| 33,45 | 19 | 10.64 | 10.64 | 10.64 | 10.64 | 10.64 | 10.64 | 10.64 | 10.64 | 10.64 | 10.64 | 10.64 | 0 | Pass |
| 33,45 | 20 | 26.59 | 26.59 | 23.93 | 26.59 | 26.59 | 26.59 | 26.59 | 23.93 | 26.59 | 26.59 | 26.058 | 1.12155 | Pass |

This test passes if the standard deviation for each defect measured is under 10.4 um. Therefore this test Is successful.
This tray can be used to Inspect all 6″ whole wafers as applicable.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

1. A device, comprising:
a semiconductor wafer holder having an opening defining a wafer engaging portion, the wafer engaging portion being resilient and adapted to securely receive a semiconductor wafer edge in an interference fit.

2. The device as specified in claim 1 wherein the wafer engaging portion has a profile substantially conforming to a perimeter of the semiconductor wafer.

3. The device as specified in claim 1 wherein the wafer holder is adapted to be received within a wafer tray cavity of a semiconductor wafer handling system.

4. The device as specified in claim 1 wherein the opening is adapted to facilitate a vacuum to couple to a received wafer.

5. The device as specified in claim 1 wherein the wafer engaging portion is comprised of a silicon sponge material.

6. The device as specified in claim 1 wherein the wafer holder has an outer perimeter, wherein the wafer engaging portion is concentric with the outer perimeter.

7. The device as specified in claim 1 wherein the wafer engaging portion comprises an opening edge having a profile commensurate with the semiconductor wafer.

8. In combination:
a semiconductor wafer having an outer edge; and
a semiconductor wafer holder having an opening defining a wafer engaging portion, the wafer engaging portion being resilient and securely receiving the semiconductor wafer outer edge in an interference fit.

9. The combination as specified in claim 8 wherein the wafer engaging portion has a profile substantially conforming to a perimeter of the semiconductor wafer perimeter.

10. The device as specified in claim 8 wherein the wafer holder is adapted to be received within a wafer tray cavity of a semiconductor wafer handling system.

11. The device as specified in claim 8 wherein the opening is adapted to facilitate a vacuum to couple to a received wafer.

12. The device as specified in claim 8 wherein the wafer holder is comprised of a silicon sponge material.

13. The device as specified in claim 8 wherein the wafer engaging portion has an outer perimeter, wherein the wafer engaging portion is concentric with the outer perimeter.

14. The device as specified in claim 8 further comprising a wafer tray receiving the wafer holder and the semiconductor wafer.

15. The device as specified in claim 14 further comprising a sticky tape securing the wafer holder to the wafer tray.

16. The device as specified in claim 15 wherein the sticky tape is removable by applying a UV light.

17. The device as specified in claim 15 wherein the sticky tape is isolated from the semiconductor wafer.

18. The device as specified in claim 15 wherein the wafer tray further includes openings adapted to permit a vacuum to couple to a received wafer.

19. A method of processing a semiconductor wafer, comprising:
disposing the semiconductor wafer in a holder comprising a semiconductor wafer holder having an opening defining a wafer engaging portion, the wafer engaging portion being resilient and securely receiving a semiconductor wafer edge in an interference fit;
disposing the wafer holder to a wafer tray holder such that the semiconductor wafer is secured with respect to the wafer tray holder; and
performing a semiconductor process on the semiconductor wafer.

20. The method as specified in claim 19 further comprising the step of disposing sticky tape between only the wafer holder and the wafer tray.

21. The method as specified in claim 20 further comprising the step of removing the sticky tape from between the wafer holder and the wafer tray using UV light.

22. The method as specified in claim 21 further comprising the step of removing the semiconductor wafer from the wafer holder using a vacuum.
